(19) United States
(12) Patent Application Publication
(10) Pub. No.: US 2026/0031176 A1
(43) Pub. Date: Jan. 29, 2026

(54) ERROR DETECTION, ERROR CORRECTION OR ERROR DETECTION AND CORRECTION (EDAC) FOR ELECTRONIC DEVICES, ELECTRONIC CIRCUITS OR ELECTRONIC SYSTEMS

(71) Applicant: ZERO-ERROR SYSTEMS PTE. LTD, Singapore (SG)

(72) Inventors: Kwen Siong CHONG, Singapore (SG); Wei SHU, Singapore (SG); Ne Kyaw Zwa LWIN, Singapore (SG); Joseph Sylvester CHANG, Singapore (SG); Arunjai MITTAL, Singapore (SG)

(21) Appl. No.: 18/998,513

(22) PCT Filed: Jul. 26, 2023
(86) PCT No.: PCT/IB2023/057594

§ 371 Date: Jan. 26, 2025

(30) Foreign Application Priority Data
Jul. 26, 2022 (SG) 10202250576A

(51) Int. Cl. G11C 29/52; G11C 29/00

(52) U.S. Cl. CPC G11C 29/52; G11C 29/785

(57) ABSTRACT

An electronic apparatus for detecting or correcting or detecting and correcting at least one datum error in an electronic device or electronic circuit or electronic system is disclosed. The electronic apparatus comprises a controller and a first memory that is connected with the controller and has a first data with an error or a number of errors. The electronic apparatus also comprises a second memory that is connected with the controller and has a second data with no error or with a number of errors that is lower than the number of errors in the first memory, and that is in some fashion related to or resembling the first data. The controller performs the error detection or the error correction or both the error detection and the error correction to the first data by using the second data.

### CROSS-REFERENCE TO RELATED APPLICATION

The present application is a filing under 35 U.S.C. 371 as the National Stage of International Application No. PCT/IB2023/057594, filed Jul. 26, 2023, entitled “ERROR DETECTION, ERROR CORRECTION OR ERROR DETECTION AND CORRECTION (EDAC) FOR ELECTRONIC DEVICES, ELECTRONIC CIRCUITS OR ELECTRONIC SYSTEMS,” which claims priority to Singapore Application No. 10202250576A filed with the Intellectual Property Office of Singapore on Jul. 26, 2022, and entitled “Low Soft-Error-Rate (SER) with Error Detection and Correction (EDAC) for Electronic Devices,” both of which are incorporated herein by reference in their entirety for all purposes.

### TECHNICAL FIELD

Various embodiments relate to detecting, correcting or detecting and correcting errors in the memory of electronic devices, circuits or systems.

### Background

In high-reliability applications including space/satellite high-level autonomous vehicles, etc., the reliability of electronic devices (including integrated circuits (ICs), System-on-Chip (SoC), System-in-Package (SiP), etc.; henceforth termed ICs) in their electronic devices, circuits and systems is one of the most important design considerations. To enhance the reliability of ICs, they must, where possible, be protected/mitigated from all possible anomalies, including errors when data is written into memory, when the data is stored in memory, and when data is read from the memory. These anomalies are well established, including that due to circuit related parameters such as voltage supply variations, deterioration of certain circuit functionalities, heat, timing errors, circuit errors, etc., and external parameters such as radiation effects arising from energized heavy-ion particles, alpha particles, protons, neutrons, etc., collectively termed ionizing particles.

One of the radiation effects is an error arising from Single-Event-Upset (SEU), where upon an ionizing particle striking an IC, a datum (a digital bit) in the said IC may be flipped from logic ‘1’ to logic ‘0’ or vice-versa, hence an error. The logic ‘1’ and logic ‘0’ are Boolean logic conditions where logic ‘1’ may be represented as true-logic whose voltage level is close to supply voltage (V_{DD})), and the logic ‘0’ may be represented as false-logic whose voltage level is close to ground (GND). The SEU may corrupt the Boolean logic condition, causing the IC to produce erroneous data. Should a 2-bit or multiple-bit data corruption occur, a Multiple-Event-Upset (MEU) event has occurred. The rate of occurrence of erroneous data is often termed as the soft-error-rate (SER), that may qualify the degree of data integrity of the electronic device, circuit or system.

Of the various ICs, memory ICs are often the electronic devices that ascertain the overall data integrity of electronic systems. The memory ICs include both volatile and non-volatile memories. Volatile memories include static random array memory (SRAM), dynamic random array memory (DRAM), register files, content-addressable memory (CAM), etc. Non-volatile memories include Read-Only-Memory (ROM), Programmable ROM (PROM), Erasable PROM (EPROM), electrically EPROM (EEPROM), flash memory, ferroelectric random array memory (FRAM), etc. For high data integrity, the SER of memory ICs needs to be very low, preferably <10⁻¹⁰ per bit per day for space/satellite applications and even lower for high-level autonomous vehicle applications, etc. Unfortunately, in harsh environments such as in space orbits, most Commercial-Off-the-Shelf (COTS) memory ICs suffer from poor data integrity, e.g., <10⁻⁴ per bit per day-their robustness to error is low.

To reduce the number of errors in memory ICs, there are generally two approaches. The first involves specific design or processes, e.g., radiation-hardened (rad-hard) memory IC whose memory cells can inherently mitigate the SEU effect. The SER of rad-hard memory ICs could be reduced by a few orders of magnitude over COTS memory ICs. However, the design and manufacturing of rad-hard memory ICs are expensive and they do not scale well (in terms of technology nodes, speed performance, capacity, power dissipation and interface protocols) when compared to COTS memory ICs. Unsurprisingly, there are not only very limited choices but they are often outdated and generally do not meet the requirements for computationally intensive current/future applications for space/satellite, including Artificial Intelligence (AI).

The second approach is to apply redundancy techniques, including information redundancy, spatial redundancy, temporal redundancy, etc. Information redundancy may include error detection and correction (EDAC) by encoding additional information which may be employed to detect and correct erroneous data within a memory IC. Spatial redundancy may include hardware-based triple-modular-redundancy (TMR) by having three memory ICs storing the same data. The data of the three memory ICs may be voted to produce a resultant output, i.e., when at least two out of three data are the same, the resultant output will adopt the majority identical data. Temporal redundancy may include software-based TMR by executing the same data three times within the same (or different) memory IC. When at least two out of three data are the same, the resultant output will adopt the majority identical data. The choice for the selection of the specific redundancy technique(s) may depend on trade-off considerations, including the speed, power, form factor, interface protocol, targeted SER, etc.

All these prior-art design/circuit implementations of redundancy techniques are homogenous in the sense that they employ COTS ICs/building blocks/circuits having similar SER vis-à-vis the same with different SER, including where the SER is significantly lower. Further, the cost or overheads of these prior-art implementations of redundancy techniques are expensive in terms of hardware, power dissipation, speed, etc., in part because their redundancy typically employ three entirely duplicated data (including encoded bits) vis-à-vis non-entirely duplicated data. In summary, the prior-art redundancy suffers from two unresolved shortcomings. First, their SER reduction (after redundancy) remains insufficient in harsh environments such as in irradiated space or in applications where the SER needs to be very low, their ensuing SER is often unacceptably high. Second, their cost or overheads remains unacceptably high.

### SUMMARY

In an embodiment, an electronic apparatus for detecting or correcting or detecting and correcting at least one datum error in an electronic device or electronic circuit or electronic system is disclosed. The electronic apparatus comprises a controller and a first memory that is connected with the controller and has a first data with an error or a number of errors. The electronic apparatus also comprises a second memory that is connected with the controller and has a second data with no error or with a number of errors that is lower than the number of errors in the first memory, and that is in some fashion related to or resembling the first data. The controller performs the error detection or the error correction or both the error detection and the error correction to the first data by using the second data.

In another embodiment, an electronic apparatus for detecting or correcting or both detecting and correcting at least one datum with error in an electronic device or electronic circuit or electronic system is disclosed. The electronic apparatus comprises a first memory having a first data with an error or a number of errors. The electronic apparatus also comprises a second memory having a second data whose information is either identical to, or in some fashion related to or resembling the first data. The error detection or the error correction or both the error detection and the error correction to the first data is based on using the second data.

In yet another embodiment, a method to detect or correct or both detect and correct at least one datum with error in an electronic device or electronic circuit or electronic system is disclosed. The method comprises at least one of detecting an error to a first data in a first memory or correcting the error to the first data in the first memory using a second data stored in a second memory. The second data of the second memory is either identical to, or in some fashion related to or resembling the first data of the first memory.

### BRIEF DESCRIPTION OF THE DRAWINGS

In the drawings, like reference characters generally refer to like parts throughout the different views. The drawings are not necessarily to scale, emphasis instead generally being placed upon illustrating the principles of the present disclosure. In the following description, various embodiments are described with reference to the following drawings, in which:

FIG. 1 (prior-art) depicts a memory system configuration where a Memory Module is interfaced with a Controller Module via an Interface Protocol.

FIG. 2A (prior-art) depicts a standard memory architecture having an Address Decoder, an I/O Circuit, and a Memory Cell Array.

FIG. 2B (prior-art) depicts a memory architecture having an Address Decoder, an I/O Circuit, a Memory Cell Array and an EDAC circuit. The Memory Cell Array has not only the memory cells storing the data, but also extra memory cells storing the encoded bits (e.g., parity/check bits, collectively termed as encoded information).

FIG. 2C (prior-art) depicts a TMR memory design having three memory ICs and a Voter Circuit.

FIG. 3 depicts the first embodiment of the present disclosure—an electronic apparatus comprising a memory system where a Controller Module is interfaced with a First Memory Module via a First Interface Protocol, and with a Second Memory Module via a Second Interface Protocol.

FIG. 4 depicts the memory data arrangement in the First Memory IC and the Second Memory IC in FIG. 3 according to an embodiment of the present disclosure.

FIG. 5A depicts the default processing steps for the EDAC Processing in the Controller Module in FIG. 3 according to an embodiment of the present disclosure. FIG. 5B depicts iterative processing steps for the EDAC Processing in the Controller Module in FIG. 3 according to an embodiment of the present disclosure.

FIG. 6 depicts the second embodiment of the present disclosure-a memory architecture having an Address Decoder, an I/O Circuit, an EDAC circuit, a First Memory Cell Array and a Second Memory Cell Array.

FIG. 7 depicts the third embodiment of the present disclosure-a pipeline structure having a Datapath Combinational Logic, an EDAC Encoder, an EDAC Decoder, a First Flip-Flop, and a Second Flip-Flop.

FIG. 8A depicts the extension of the first embodiment of the present disclosure in FIG. 3 where the First Memory IC further comprises encoded data. FIG. 8B depicts the extension of the first embodiment of the present disclosure in FIG. 3 where the Second Memory IC further comprises encoded data.

### DETAILED DESCRIPTION

It should be understood at the outset that although illustrative implementations of one or more embodiments are illustrated below, the disclosed systems, memory systems, memory architectures and pipeline structures may be implemented using any number of techniques, whether currently known or not yet in existence. The disclosure should in no way be limited to the illustrative implementations, drawings, and techniques illustrated below, but may be modified within the scope of the appended claims along with their full scope of equivalents.

The description herein refers to the accompanying drawings that show, by way of illustration, specific details and embodiments in which the disclosure may be applied. These embodiments are delineated in detail to enable the skilled in the art to supply the disclosure.

As used herein, the term “and/or” includes any and all combinations of one or more of the associated listed items.

Error detection and correction can be challenging because cost and accuracy/reliability are often at odds. For example, the use of standard COTS memory (data bits and parity bits) in a challenging environment may help reduce cost, but with any memory errors that arise (which happens more frequently in a challenging environment) it is difficult to know what to trust and/or be able to identify where the error is. On the other hand, hardening of memory (e.g., via Radiation-Hardened-By-Design or Radiation-Hardened-By-Process both discussed further hereinafter), which results in stronger/more radiation resistant memory across the board, may be expensive in manufacturing cost and/or in operating cost including time, processing, or power. Thus, the pending application is directed to a more robust and efficient error correction and detection system. In particular, the error correction and detection system disclosed herein may include an unhardened main memory storing data bits and a hardened memory storing parity bits, which are used to protect the data bits in the unhardened main memory. By having the memory storing the parity bits hardened, the system is able to more reliably identify and correct errors. Further, it is more efficient to have just the memory storing the parity bits hardened as opposed to all of the memory module(s).

The broad objective of the present disclosure is to reduce the error in an electronic device, circuit or system comprising memory, thereby improving (decreasing) its SER. A further objective of the present disclosure is to achieve the aforesaid with low overheads, including hardware, power, etc.

Embodiments of the disclosure pertain to detecting, correcting or detecting and correcting errors in the memory of electronic designs, leading to improved SER of memory and memory configurations by the application of homogeneous and heterogenous memory, application of entire data and non-entirely duplicated data, etc., to realize redundancy. The outcomes include reduced SER or reduced hardware/overheads for equal or reduced SER, or both, and applicable to memory and for a pipeline structure within an electronic device, circuit or system.

In an embodiment, an apparatus for detecting, correcting or both detecting and correcting errors is disclosed, thereby reducing the number of errors and its ensuing SER in an electronic device, circuit, or system. The apparatus comprises two memories. The first memory has an SER and comprises data with an error or a number of errors, and is preferably a COTS memory, albeit it can be any memory type. The second memory has another SER and comprises data, preferably with no error or a number of errors less than the first memory. The data in the second memory also comprises information that is in some fashion related to or resembling the data of the first memory.

The robustness to errors of the second memory may be less than, equal to, or higher than the first memory, i.e., its SER may be higher, equal to, or lower than the first memory. Nevertheless, in general, it is preferred that its robustness is higher (i.e., its SER is lower) than that of the first memory, and this can be derived by enabling the second memory to be different from that of the first memory. These include radiation-hardening, realized in different fabrication technology, based on different architecture and design, using redundancy, etc.

The various embodiments of the present disclosure to detecting, correcting or detecting and correcting the error or errors in the first memory are by means of leveraging on the information in the second memory that preferably features either no error or lesser errors than the first memory.

By means of the present disclosure, the hardware and other overheads of the ensuing embodiments of the present disclosure are lower than in prior-art systems/methods for the same degree of detection, correction or both detection and correction of errors. This is, in part, by means of the aforesaid number of attributes of the second memory that are different from that of the first memory.

In the electronic device, circuit, or system, the embodiments of the disclosure apply to one or a combination of the following: a memory system configuration, memory architecture, data pipeline structure, etc.

As mentioned above, the present disclosure involves means to detect, correct or detect and correct an error in the memory of an electronic device, circuit or system, comprising a first and a second memory. The second memory is preferably more robust to errors than the first memory, i.e., its SER is preferably lower than the first memory; if the second memory is less robust, it can be designed or configured to be more robust by one or more means. The second memory comprises data (or sub-data) where the information therein is in some fashion related or resembling the data of the first memory. The present disclosure detects, corrects or detects and corrects an error (or errors) in the first memory by leveraging on the data or sub-data in the second memory.

The said leveraging in the present disclosure, exemplified in the first, second and third embodiments, is illustrated with the means to adopt an EDAC approach/algorithm. The present disclosure is applicable to a memory system configuration, a memory architecture, a pipeline structure, etc. Note that the present disclosure is also applicable to an electronic device, circuit or system that does not embody an EDAC approach/algorithm, but embodying any other corrective approach/algorithm to reduce its (overall) SER of the electronic system/design.

The embodiments discussed herein reduce the SER of the electronic system/design by mitigating the effects of fault(s) on the memory. The fault may be due to one or more of the following combinations: (a) during the writing into (the address of) the memory (location) that would store the datum or data, (b) an erroneous change of the datum or data during storage, and (c) during the reading of the (address of the) memory (location) that embodies the datum or data.

The error(s) during the writing, storage and reading may be due to a number of reasons described earlier. Of interest, in a harsh environment such as space, the error may be due to ionizing particles, such as heavy-ion particles, alpha particles, protons, neutrons, radioactive elements, but not limited to other sources of errors such as electromagnetic waves, lasers, noises during abnormal current/voltage disruptions, etc.

We will first delineate the first embodiment (and their variations) of the present disclosure in the perspective of system configuration. Thereafter, we will delineate the second embodiment of the present disclosure in the perspective of architecture. Finally, we will delineate the third embodiment of the present disclosure in the perspective of a pipeline structure.

Throughout this description, the term “signal” or “datum” and “signals” or “data” may be used interchangeably where “signal” or “datum” may mean more than one signal or one bit datum. The term “data” may mean one bit datum or more bits, and “input data” and “output data” may include both data and control signals. The term “information” may refer to signal information or data information. Finally, “rad-hard”, “radiation-hardened” and “hardened” may be used interchangeably, as are “non-rad-hard”, non-radiation-hardened, and “unhardened”.

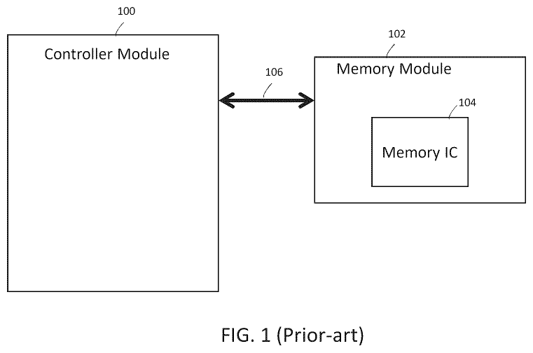

FIG. 1 depicts a prior-art system configuration having a Controller Module 100 and a Memory Module 102. The Controller Module 100 may be a digital processor, including a microcontroller, microprocessor, Field-Programmable-Gate-Array, state-machine, etc., controlling the read/write access of the Memory Module 102. The Memory Module 102 may comprise at least a Memory IC 104 or circuit capable of storing data. The Controller Module 100 and the Memory Module 102 are interfaced via Interface Protocol 106. The Interface Protocol 106 may contain the memory interface signals (such as inputs, outputs, address, read/write and control signals) to write/read data between the Controller Module 100 and the Memory IC 104 of the Memory Module 102. The Interface Protocol 106 may also be the prevalent communication protocols such UART, SPI, I²C, DDR2/3/4, PCI-e 1/2/3/4/5, Spacewire, eMMC 4.41/4.5/5.0/5.1, UFS 1.0/2.0-2.2/3.0-3.1, or any communications protocols—the present disclosure is independent on the specific communication protocols. The communication protocols and others may encode the abovementioned memory interface signals to perform the read/write operation for the Memory IC 104 of the Memory Module 102. The prevailing communication protocols and others may be in a serial (bit-wise) data communication, parallel (bus-wise) data communication, or a combination thereof.

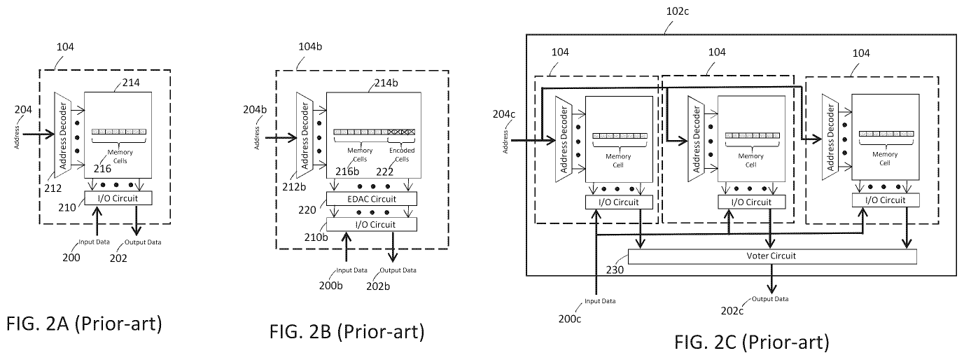

FIG. 2A depicts a simplified block diagram of prior-art Memory IC 104, having the Input Data 200, Output Data 202, and Address 204 signals. The Memory IC 104 comprises an I/O Circuit 210, an Address Decoder 212, and a Memory Cell Array 214. The I/O Circuit 210 may control the read/write operation. For a write operation, depending on the Address signal 204, the Input Data 200 may contain the write access signal and the input signals so that the I/O Circuit 210 may write the input signals into Memory Cells 216. For a read operation, depending on the Address signal 204, the Input Data 200 may contain the read access signal so that the I/O Circuit 210 may read the data stored in the Memory Cells 216 to the Output Data 202. For illustration, within the Memory Cell Array 214, the Memory Cells 216 have 8-bit data; each shaded box represents 1-bit datum. Within the Memory Cell Array 214, there may be one or more Memory Cells 216.

The Memory IC 104 may be a COTS memory IC which could operate at high frequency (e.g., >200 MHz) and could have a large memory capacity (e.g., ≥1G bytes (1 GB)). However, in terms of radiation hardness, the COTS memory IC could be weak, i.e., it is not robustness to errors, thereby usually suffering from poor SER, e.g., <10⁻⁴ per bit per day.

FIG. 2B depicts a simplified block diagram of prior-art Memory IC 104b embodying information redundancy. The Input Data 200b, Output Data 202b, and Address 204b may be respectively the signal-equivalent to the Input Data 200, Output Data 202, and Address 204 of Memory IC 104 in FIG. 2A. The I/O Circuit 210b and Address Decoder 212b may be respectively the functionality-equivalent circuits to the I/O Circuit 210 and Address Decoder 212 of Memory IC 104 in FIG. 2A. The Memory IC 104b may further comprise an EDAC Circuit 220 and a Memory Cell Array 214b having not only the Memory Cells 216b but also Encoded Cells 222.

The prior-art information redundancy may be achieved by having the EDAC circuit 220 and the Encoded Cells 222. Depending on the Address signal 204b, for a given input signal to be stored into the Memory Cells 216b, the EDAC circuit 220 may generate encoded information to be stored into the Encoded Cells 222. The encoded information may contain the parity/check bit signals based on the given input signal. The parity/check bit signals may be used to detect and/or correct the stored input signal in the Memory Cells 216b which may be corrupted by SEU or other mechanisms delineated earlier.

For example, during a read operation, depending on the Address signal 204b, the Input Data 200b may contain the read access signal so that the I/O Circuit 210b may read the data stored in the Memory Cells 216b and that in the Encoded Cells 222. The EDAC Circuit 220 may check the encoded information in the Encoded Cells 222 against the data in the Memory Cells 216b. If a datum in Memory Cells 216b is corrupted, the encoded information in the Encoded Cells 222 may be used to detect the error and correct the error so that the final output to the Output Data 202b may remain error-free.

There are various error detection and correction algorithms, including Cyclic Redundancy Check, Hamming Code, Bose-Chaudhuri-Hocquenghem (BCH) Code, Berger Code, Reed-Solomon Code, Low Parity Density Code, etc. For illustration in FIG. 2B, within the Memory Cell Array 214b, the Encoded Cells 222 have 4-bit data; each shaded box with an “X” representing 1-bit datum. The 4-bit encoded information in the Encoded Cells 222 is based on Hamming Code which is sufficient to detect and correct 1-bit error within the 8-bit data in the Memory Cells 216b. In this modality, the 4-bit (encoded) is the sub-data and the 8-bit is the data.

The Memory IC 104b may be a COTS memory IC where both the Memory Cells 216b and the Encoded Cells 222 are within the same memory IC. As the Memory Cells 216b and the Encoded Cells 222 are homogeneous cells, the SER reduction may depend on the specific error mechanism. In the case of ionizing particles, this would depend on the hit rate on the Memory Cells 216b and the Encoded Cells 222. As the Memory Cells 216b is often larger than the Encoded Cells 222, an SER reduction may be achievable, in part because the sensitive area of the Encoded Cells 222 is smaller than that of the Memory Cells 216b, and because of the potential to correct the errors in the Memory Cells 216b. However, if there are multi-bit errors (i.e., MEU) in the Memory Cells 216b and/or the Encoded Cells 222, the efficacy of information redundancy may be largely compromised either at the cost of more parity bits required (and the associated hardware cost), or at the cost of complex encoding/encoding process, etc.

FIG. 2C depicts a simplified block diagram of prior-art Memory Module 102c having spatial redundancy, i.e., hardware-based TMR. The Memory Module 102c may be the Memory Module 102 in FIG. 1. The Memory Module 102c comprises three Memory ICs 104 in FIG. 2A (or three Memory ICs 104b in FIG. 2B), and a Voter Circuit 230. The Input Data 200c and the Address signal 204c are connected to the three Memory ICs 104 (or 104b), and the outputs from each of the three Memory ICs may be voted via the Voter Circuit 230. The spatial redundancy may be achieved by storing the data in three separate Memory ICs. As long at least two Memory ICs generate the same outputs, the voted Output Data 202c is the same as the at least two outputs, and the output of Output Data 202c would remain error-free.

Put simply, this error-free assumption is only valid if the same bit information (in at least two out of the three Memory ICs) is error-free, and the Voter Circuit 230 has low SER (e.g., much lower than that of the Memory ICs). If the at least two out of three Memory IC outputs have identical error, the Voter Circuit 230 output will be erroneous. Such low SER Voter Circuit 230 is typically non-COTS, i.e., of special design, e.g., rad-hard, and although being rad-hard may not necessarily guarantee error-free operation, their SER is typically very low.

The spatial redundancy may be realized in many forms. For example, two memories (or other blocks) may form a dual-modular-redundancy where a comparator may be used to compare the results of the two memories. Similarly, an even higher order modular redundancy may be adopted such as having three memories, four memories, or more. In such higher modular redundancy (≥3 memories or blocks), a voter or a comparator or both a voter and a comparator may be used for comparing the results from the memories, and subsequently for correcting the results if an error is detected.

The Memory Module 102c may be a COTS memory module embodying one or more COTS Memory ICs 104. Although the present-art COTS Memory ICs 104 could operate a very high speed (e.g., >200 MHz), their SER is typically low, particularly when operating in a harsh environment. Presently, there are very limited memory ICs with low SER. Further, there is also very few Voter Circuit 230 available that feature low SER and high speed that could match the speed requirement of the present-art COTS Memory ICs. An alternative is to employ high-speed but non-rad-hard Voter Circuit 230 but this could significantly compromise the SER of the Memory Module 102c.

For completeness, FIG. 1 may also illustrate the Memory Module 102 having temporal redundancy. In FIG. 1, the temporal redundancy may be achieved by executing the data three times (for TMR) from the Memory IC 104 of the Memory Module 102. For example, for a read operation, as long as the Controller Module 100 obtains the same (identical) data at least two times (out of three), the data would be considered correct. For temporal redundancy, repeatedly writing/reading the same data in the same memory location may be not desirable. The preferred practice is to store the data at different memory locations (within the same Memory IC 104 or different Memory ICs). Specifically, executing the data three times from the different memory locations (to obtain the same data) may improve the SER. This preferred practice may be viewed as hybrid spatial-temporal redundancy. If the Memory IC 104 of the Memory Module 102 is a COTS memory IC which could be easily corrupted by a mechanism such as SEU, the efficacy of the temporal redundancy may be compromised.

Temporal redundancy may like-wisely be realized in many forms. For example, executing the data two times for the memory may form a dual-modular-redundancy for comparing the results from the two times of execution. Similarly, an even higher order modular redundancy may be adopted such as executing the data three times, four times, or more. In such higher modular redundancy (with multiple times of execution), a voting process or a comparison process or both a voting process and a comparison process may be adopted to detect any possible error or its subsequent data correction.

In summary, prior-art memory ICs and/or memory modules (see FIGS. 1, 2A-2C) may suffer from insufficiently low SER when COTS memory ICs are employed and/or when a high-speed COTS Voter Circuit is employed. The overheads, including hardware, power, delay, etc., can also be considerable, rendering some of these prior-art methods incompatible with resource-constraint applications such as satellites, high-level autonomous vehicles, etc.

Improving the SER of prior-art memory ICs and/or memory modules may be achieved by augmenting more information redundancy, or spatial redundancy or temporal redundancy or a combination thereof. For example, a double-error correction (vis-à-vis a prevalent single-error correction) hardware implementation by doubling the parity bits used was reported by Nazeer, et al., in a conference publication entitled “Parallel Double Error Correcting Code Design to Mitigate Multi-bit Upsets in SRAMs”. A hybrid matrix consisting of 125% more parity bits over the data bits was reported by Rohde, et al., in a conference publication entitled “Multi-Bit-Upset Memory Using New Error Correction Code Methodology”. Two-dimensional parity schemes for detecting/correcting multiple-errors were reported by Rao, et al., in a conference publication entitled “Protecting SRAM-based FPGAs against Multiple Bit Upsets using Erasure Codes” and by Park, et al., in a journal publication entitled “Soft-Error-Resilient FPGAs Using Built-in 2-D Hamming Product Code”. Error estimation and repair schemes leveraging on parity bits and the associated hardware control were reported in the following US patents: “Estimation of Error Correcting Performance of Low-Density Parity-Check (LDPC) Codes,” by Tehrani, “Memory System with Error Detection and Retry Modes of Operation” by Ware, et al., “Dynamic Application of Error Correction Code (ECC) based on Error Type” by Agarwal, et al., “Combined Group ECC Protection and Subgroup Parity Protection,” by Ohmacht, et al., and “Semiconductor Memory Devices including Error Correction Circuits and Methods of Operating the Semiconductor Memory Devices,” by Choi, et al. These further SER improvement methods incur high overheads, including hardware, cost, or complex encoding/encoding process or the degree of estimation accuracy, etc.

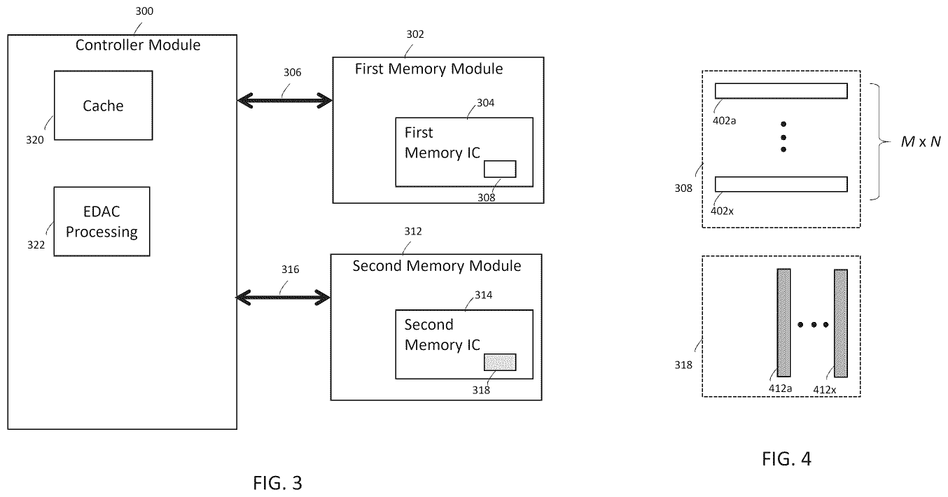

Now, consider the first embodiment of the present disclosure depicted in FIG. 3 as a memory system configuration to improve (reduce) the SER by applying a First Memory Module 302 and a Second Memory Module 312. The broad objective of the present disclosure is to detect, correct or detect and correct an error or errors in the First Memory Module 302 (or First Memory IC 304) by leveraging on the information in the Second Memory Module 312 (or Second Memory IC 314). The said information may be, for example, sub-data such as the parity bit(s) of data in the First Memory Module 302 (or First Memory IC 304)—see later.

In terms of robustness to errors or SER, the Second Memory Module 312 (or Second Memory IC 314) may be higher, the same, or lower than the First Memory Module 302 (or First Memory IC 304). Nevertheless, in view of the present disclosure leveraging on the information in the Second Memory Module 312 (or Second Memory IC 314), it is preferable (i.e., not absolutely necessary) that the Second Memory Module 312 (or Second Memory IC 314) feature higher robustness or lesser errors (i.e., lower SER) than the First Memory Module 302 (or First Memory IC 304). This is to derive more efficacious error detection, correction or detection and correction.

To enhance the robustness of Second Memory Module 312 (or Second Memory IC 314) it may be different from the First Memory Module 302 (or First Memory IC 304) by one or a combination of the following parameters: (a) physical address on the same or different integrated circuit die, (b) having one or more copies of the data that is some fashion related to or resembling the data in the First Memory Module 302, (c) integrated circuit die, (d) data capacity (size) of the data in the Second Memory Module 312, (e) fabrication process, (f) layout including the number or type of ring-guards, (g) interfacing circuit, (h) architecture or topology, (i) transistor configuration, (j) parasitic capacitance, (k) speed or delay, (l) power dissipation, (m) integrated circuit area, (n) operating voltage, (o) Radiation-Hardened-By-Design, or (p) Radiation-Hardened-By-Process, etc.

Related to Radiation-Hardened-By-Design, the technique may be the transistor upsizing by increasing the width of the transistors, hence having a stronger current drivability to suppress the induced electron-hole pairs when a high energy particle hits the transistors. Other Radiation-Hardened-By-Design techniques may include the insertion of the filter gates/circuits to attenuate the transient pulse, the redundant circuits such as DICE (dual-interlocked cell) to repair a corrupted bit, and other redundancy techniques including TMR which has been discussed earlier.

Related to Radiation-Hardened-By-Process, the technique may be using the Silicon-on-Insulator (SOI) fabrication process which may have less error-rate than the bulk CMOS process. Other techniques may include the use of Silicon on Sapphire (SOS) or the use of some special layout techniques, e.g., annular layout which may only be permitted in certain fabrication process technologies.

In view of the aforesaid, both the First Memory Module 302 (or First Memory IC 304) and the Second Memory Module 312 (or Second Memory IC 314) may be based various COTS memories, e.g., consumer-grade SRAM, DRAM, Flash, etc., used in everyday electronic devices. Where different COTS memories are available, it is preferable that the Second Memory Module 312 (or Second Memory IC 314) feature higher robustness to errors (i.e., less SER) than First Memory Module 302 (or First Memory IC 304) for sake of the efficacy of the present disclosure.

The First Memory Module 302 may be interfaced with the Controller Module 300 via a First Interface Protocol 306. The First Interface Protocol 306 may be the DDR2/3/4, PCI-e 1/2/3/4/5, Spacewire, eMMC, etc. In this case, the First Memory IC 304 may be a high-speed memory which may support high bandwidth data transfer and may have large memory capacity. The First Interface Protocol 306 may also be the UART, SPI, I²C, other general purpose Inputs/Outputs, etc. In this case, the First Memory IC 302 may be a mid-speed/low-speed memory which may or may not necessarily have large memory capacity.

The Second Memory Module 312 may be interfaced with the Controller Module 300 via a Second Interface Protocol 316. The Second Interface Protocol 316 may be of any communications protocol, including the UART, SPI, I²C, etc., and may also be the same as the First Interface Protocol 306. The Second Memory IC 314 may be of any type, albeit in many practical applications for sake of lower overheads, including hardware, power, etc., a low-speed memory may be preferred. The preferred low-speed memory may or may not necessarily support fast bandwidth data transfer, and may or may not necessarily have large memory capacity.

Put simply, all types of memory and all types of communications protocols for the First Interface Protocol 306 and for the Second Interface Protocol 316 are applicable—the present disclosure is independent of the communications protocol. To achieve high efficacy (i.e., SER reduction in the First Memory Module 302 (or First Memory IC 304)) of the present disclosure, it is preferred (albeit not absolutely necessary) that the Second Memory Module 312 (or Second Memory IC 314) features a lower SER than the First Memory Module 302 (or First Memory IC 304); it is also preferred that the EDAC Processing 322 and the Cache 320 in FIG. 3 feature low SER.

The broad basis of the present disclosure to detect, correct or detect and correct an error in the First Memory Module 302 (or First Memory IC 304), thereby achieving lower errors or SER, is by leveraging on the information in the Second Memory Module 312 (or Second Memory IC 314). One set of processing steps to achieve a lower SER for the invented memory system configuration over the prior-art methods will now be delineated; note that there are other possible steps, particularly for one who is skilled in the art and employing this disclosure.

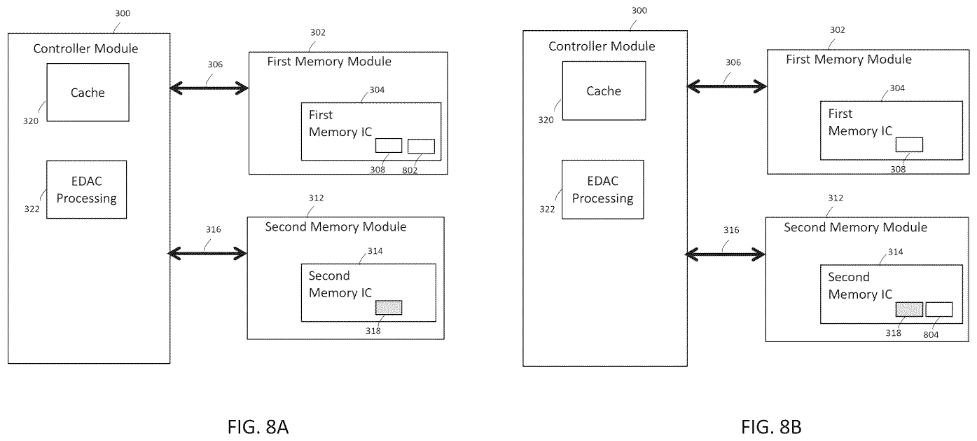

Consider first the write operation and thereafter the read operation. During a write operation, the data in the Cache 320 in the Controller Module 300 needs to be transferred via the First Interface Protocol 306 to the First Memory IC 304 of the First Memory Module 302; the data written into the First Memory IC 304 may be viewed as the stored data 308 which may be subject to the mechanisms of error, e.g., SEU/MEU, etc., over time. The transfer may be in a block transfer where the size of each data transfer may be 16 B or any other number of bytes or bits. Meanwhile, the same data stored in the Cache 320 may be processed by an EDAC Processing 322 which encodes the data into encoded information which may be able to check and repair the stored data in the First Memory IC 304 (if there is any error over time). The encoded information may be viewed as the data integrity information of (written into) the Stored Data 308 in the First Memory IC 304, and is hence in some fashion related to or resembling the first data of the first memory. The encoded information may be transferred to the Second Memory Module 312 which will be delineated in the following paragraphs, or to the First Memory Module 302 as another variation which will be depicted and delineated in FIG. 8 later.

For the data transfer into the Second Memory IC 314, the encoded information may also be transferred via the Second Interface Protocol 316. The encoded information may become (be written) the Stored Encoded Information 318 when it has been stored in the Second Memory IC 314. If the data size to be written into the Second Memory IC 314 of the Second Memory Module 312 is larger than the size of each data transfer, multiple times of data transfer may be needed.

Note that because the Second Memory Module 312 preferably features higher robustness to errors (i.e., lower SER) than the First Memory Module 302, the stored encoded information 318 would ensuingly be more tolerant against errors, e.g., against SEU. Some of the possible ways to enhance the robustness of the Second Memory Module 312 (or Second Memory IC 314) over the First Memory Module 302 (or First memory IC 304) were delineated in (a)-(p) earlier.

Further, as the encoded information is lesser (e.g., lesser number of bits) than the actual data, it is hence innately less prone to error (i.e., lower SER). In this sense, it is possible that the specific type of Second Memory Module 312 (or Second Memory IC 318) can be identical to that of the First Memory Module (or First Memory IC 308), yet the Second Memory Module 312 (or Second Memory 318) is more robust to errors than First Memory Module 302 (or First memory IC 304). In this fashion, the First Memory Module 302 and the Second Memory Module 312 may be the same memory module or two separate memory modules. Similarly, the First Memory IC 304 and the Second Memory 314 may then be in the same memory IC die or two separate memory IC dies.

Consider now the read operation. For a read operation, the Stored Data 308 in the First Memory IC 304 of the First Memory Module 302 needs to be transferred via the First Interface Protocol 306 back to the Cache 320 of the Controller Module 300. The data transfer may be in a block transfer where the size of each data transfer may be 16 B or any other number of bytes or bits. Meanwhile, the Stored Encoded Information 318 in the Second Memory IC 314 of the Second Memory Module 312 needs to be transferred via the Second Interface Protocol 316 to the EDAC Processing 322. The EDAC Processing 322 may check the Stored Encoded Information 318 against the Stored Data 308 from the First Memory IC 304—the encoded information and stored data may be now in the Cache 320.

If the Stored Data 308 read from the First Memory IC 304 is corrupted (i.e., erroneous), the EDAC Processing 322 may use the Stored Encoded Information 318 read from the Second Memory IC 314 to detect, correct or detect and correct the error. Hence, the final data may remain error-free within the Controller Module 300 for subsequent operations. As delineated earlier, because the Second Memory Module 312 is more robust to errors (e.g., it being radiation-hardened) than the First Memory Module 302 (e.g., it being COTS), the Stored Encoded Information 318 would be more tolerant to errors, e.g., SEUs. If the data size to be read out of the COTS Memory IC 304 of the COTS Memory Module 302 is larger than the size of each data transfer, multiple times of data transfer may be needed.

In view of the abovementioned write/read operations involving an EDAC processing, the write operations may be viewed as an encoding process and the read operations as a decoding process.

For simplicity in the claim section later, the Stored Data 308 may be viewed as the first data within the first memory (i.e., First Memory IC 304), and the first data (i.e., Stored Data 308) may comprise a datum (1 bit) or many data (multiple bits). The Stored Encoded Information 318 may be viewed as the second data within the second memory (i.e., Second Memory IC 314), and the second data (i.e., Stored Encoded Information 318) may comprise a datum (1 bit) or many data (multiple bits).

Note that the First Interface Protocol 306 and the Second Interface Protocol 316 may be the same or different in terms of the interface signals and/or speed requirements. The present disclosure is independent of the protocols.

The data capacity (i.e., total size of the data) of the Stored Data 308 in the First Memory Module 302 could be the same or different from the Stored Encoded Information 318 in the Second Memory Module 312, in part depending on the compression ratio in adopted EDAC algorithm. For example, using the Hamming Code, an 8-bit (1 B) encoded information may be used to check/correct 16 B data whereas 16-bit (2 B) encoded information may check/correct 4,096 B data. Viewed differently, using 1 B coded information for Hamming Code, the First Memory Module 302 with 8 GB data may be protected by the Second Memory Module 312 with 516 MB encoded data. Should 2 B encoded information be used, the First Memory Module 302 with 8 GB data may be protected by the Second Memory Module with 2 MB encoded data. The number of bits for the encoded information may be increased by adding more parity bits to protect the same amount of data. In this case, the compression ratio in the EDAC algorithm may be compromised but the data integrity of the data may be further protected, e.g., by enabling multi-bit error correction. As delineated earlier, note that the First Memory Module 302 and the Second Memory Module 312 may be within the same memory module or they may be separate memory modules. Similarly, the First Memory IC 304 and the Second Memory IC 314 may be within the same memory IC or they may be separate memory ICs.

The Stored Data 308 may be arranged to have a number of sub-data sets, e.g., sub-data-1 402a to sub-data-x 402x in FIG. 4. The data arrangement may be in any arbitrary block size M×N where M is the wordlength of a sub-data, and Nis the number of the sub-data sets. The wordlength M may be 8 bits or larger than 8 bits. The Stored Encoded Information 318 may be the corresponding encoded information for the Stored Data 308. The Stored Encoded Information 318 may be generated based on one or a combination of codes, including the Hamming code, the parity code, the cyclic code, or a hash function, etc. For example, the Partial Encoded Information 412a may be the Hamming code encoded for the Sub-data-1 402a or for any other sub-data, such as the Sub-data-x 402x. The other Partial Encoded Information 412x may be that encoded for other information such as the parity bit based on the Sub-data-1 402a or other sub-data such as the Sub-data-x 402x. Alternatively, the other Partial Encoded Information 412x may be that encoded for other information such as the parity bit based on the bits across different sub-data, e.g., across the least significant bits from the Sub-data-1 402a to the Sub-data-x 402x. Put simply, the Partial Encoded Information 412a and/or other Partial Encoded Information 412x may be collectively encoded using the Hamming code, parity code, cyclic code, a hash function, etc., or a combination of these codes by referencing any bitstream arrangement (i.e., horizontal, vertical, diagonal or a random sequence) based on the arbitrary block size M×N of the Stored Data 308. The Partial Encoded Information 412a and other Partial Encoded Information 412x may be collectively used to perform multiple-bit error detection and correction where the Partial Encoded Information 412a may detect or correct or detect and correct some errors, and the other Partial Encoded Information 412x may detect or correct or detect and correct other errors for the Stored Data 308.

When the Stored Data 308 and the Stored Encoded Information 318 have been transferred to the Controller Module 300, the EDAC Processing 322 may perform the error detection, error correction or error detection and correction algorithm in one of the many ways. We will delineate two ways while one skilled in the art may suggest other ways but embodying the present disclosure.

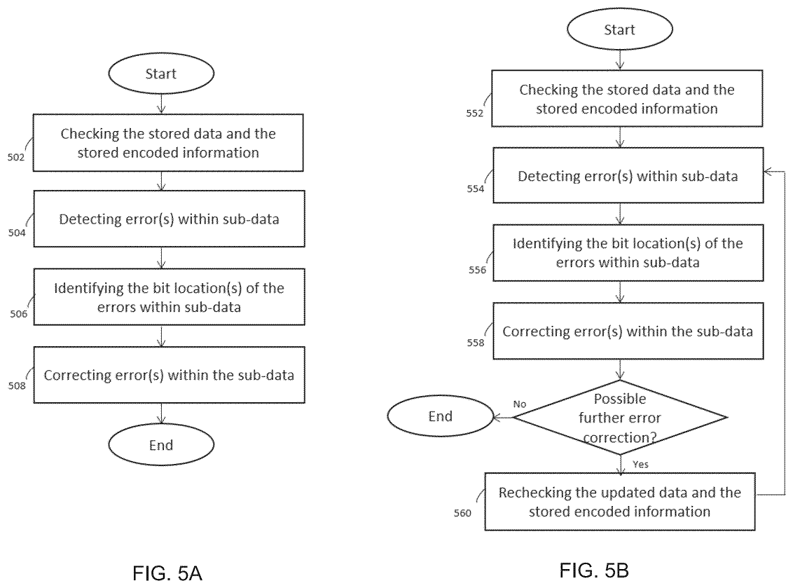

In one way, as illustrated in FIG. 5A, the EDAC Processing 322 may first check the Stored Data 308 and the Stored Encoded Information 318 (see Processing Step 502), detect at least one error within a sub-data of the Stored Data 308 (see Processing Step 504), identify the bit location(s) for the at least one error within the sub-data of the Stored Data 308 (see Processing Step 506), and correct the at least one error within the sub-data of the Stored Data 308 (see Processing Step 508). The Processing Steps 502, 504, 506 and 508 may be applied to each sub-data one by one (i.e., sequential operations) until all the sub-data are checked for the possible error detection and correction. Alternatively, the Processing Step 504 may be first applied to all the sub-data for error detection, then the Processing Step 506 may be applied to all the sub-data for error bit location identification, and finally the Processing Step 508 may be applied to all the sub-data for error correction.

In another way, as illustrated in FIG. 5B, the EDAC Processing 322 may perform iterative error detection and correction. The EDAC Processing 322 may first perform the Processing Steps 552, 554, 556 and 558 which may be the same as those in the Processing Steps 502, 504, 506 and 508, respectively. Thereafter, the EDAC Processing 322 may further check if there is any further error correction in any of the sub-data of the Stored Data 308. If there is, the EDAC Processing 322 may use the Stored Encoded Information 318 to check against the updated data (where some errors may be corrected earlier)—refer to the Processing Step 560. Thereafter, the Processing Steps 554, 556, and 558 may be repeated. The processing steps may be terminated when no further error correction is possible. Such termination condition may be defined as when all the errors have been corrected or the bit location(s) of the errors are not possible to be further detected.

The data transfer between the Controller Module 300 and the First Memory Module 302 and that between the Controller Module 300 and the Second Memory Module 312 may be in any arbitrary sequence. For example, a portion of data may be transferred to/from the First Memory Module 302, followed by a portion of the encoded information transfer to/from the Second Memory Module 312. Similarly, the sequence could be reversed by first transferring the portion of the encoded information followed by the portion of the data. The activation of the data/encoded information transfer may be initiated by the Controller Module 300. The execution in the Controller Module 300 may be performed by software means (e.g., using a microcontroller), and/or by dedicated hardware means (e.g., a Field-Programmable-Gate-Array (FPGA)), or by other means.

There are several possible implementation variations for the first embodiment of the disclosure as depicted in FIG. 3. As the first example/variation, noting, as delineated earlier, that if the specific type of the Second Memory Module 312 (or Second Memory IC 344) is identical to the First Memory Module 302 (or First Memory IC 304) and if the encoded data in the former is smaller (e.g., less number of bits) than the data in the latter, the former is already more robust to errors than the latter.

The second example/variation involves rad-hard/rad-tolerant memory. If the Second Memory IC 314 in FIG. 3 is rad-hard/rad-tolerant, it would feature lower SER than the First Memory IC 304 (assuming it is COTS). For example, for an 8-bit data, if the First Memory IC 304 has an SER of 1×10⁻³ per day, lowering the SER of the rad-hard/rad-tolerant memory IC 314 from 1×10⁻³ per day to 0.5×10⁻³ could improve the overall SER from about 2 to 4 times. In general, the lower the SER of the rad-hard memory IC (for the Second Memory IC 314), the better is the SER reduction (i.e., lower SER) for the overall memory system configuration in FIG. 3. Nonetheless, it is always desirable that the SER of the First Memory IC 304 to be low, so that the overall SER of the memory configuration system in FIG. 3 is even lower.

In the third example/variation, the Second Memory IC 314 in FIG. 3 adopts a TMR topology depicted in FIG. 2C. In the TMR memory depicted in FIG. 2C, three dedicated COTS Memory ICs 104 and a dedicated Voter Circuit 230 are adopted. In general, the TMR memory would be more robust against errors and feature lower SER than the Memory IC 304 (assuming it is COTS without TMR). The SER would also reduce if the Voter Circuit 230 features lower SER. For example, for an 8-bit data, if the Second Memory IC 304 and the Memory ICs 104 have an SER of 1×10⁻³ per day, lowering the SER of the rad-hard/rad-tolerant Voter Circuit 230 from 1×10⁻³ per day to 0.5×10⁻³ per day could improve the overall SER to about 4 times to 8 times.

Note that in this third example/variation, other methods to improve the robustness of the Second Memory IC may be used. As delineated earlier, this includes one or a combination of methods (a)-(p), etc., delineated earlier.

For the aforesaid second and third examples/variations, the Second Memory IC 314 may feature low SER, e.g., <10⁻⁵ per bit per day—2 orders of magnitude better SER. For the second example/variation, the dedicated Voter Circuit 230 may be rad-hard/rad-tolerant.

The fourth example/variation involves improving the robustness of either the Cache 320 or the EDAC Processing 322, or both, to errors. In a space application, radiation-hardening is appropriate although any one or a combination of methods (a)-(p), etc., delineated earlier may be also appropriate.

The fifth example/variation may be using redundancy based on the Stored Data 308 and the Stored Encoded Information 318. For example, the Stored Data 308 and the Stored Encoded Information 318 may be the same or different. Should the Stored Data 308 and the Stored Encoded Information 318 be the same, the data protection may be by means of dual-modular-redundancy. Should the Stored Data 308 and the Stored Encoded Information 318 be different, the data protection may be achieved via EDAC as described earlier where the Stored Encoded Information 318 may be in some fashion related to or resembling the Stored Data 308 by means of encoding such as parity, Hamming, cyclic, hash function, etc. The Stored Encoded Information 318 may comprise multiple copies of the data where each copy of the data may be in some fashion related to or resembling the Stored Data 308. The multiple copies of data (of the Stored Encoded Information 318) may be protected by means of redundancy, from dual-modular-redundancy, TMR or higher modular redundancy (≥4). The adoption of redundancy may be in a spatial fashion (hardware-duplication), a temporal fashion (multiple executions at different times), a combination in the spatial and temporal fashions, etc.

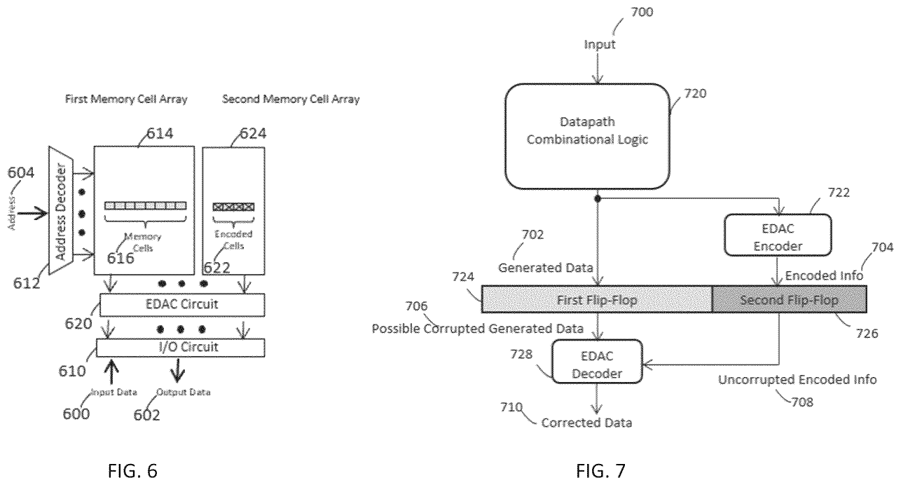

FIG. 6 depicts the second embodiment of the disclosure as the memory architecture having an I/O Circuit 610, an Address Decoder 612, a First Memory Cell Array 614, a Second Memory Cell Array 624, and an EDAC Circuit 620. The I/O Circuit 610, the Address Decoder 612, and the EDAC circuit 620 are respectively functionally equivalent to the I/O Circuit 210, the Address Decoder 212, and the EDAC circuit 220 in FIG. 2B. The First Memory Cell Array 614 may be the memory cell array having Memory Cells 616 which may store the data. The Memory Cells 616 may suffer from poor robustness to errors, i.e., its SER may be high, for example, due to SEU if it is COTS and applied in space. The Second Memory Cell Array 624 may be the memory cell array having (memory) Encoded Cells 622 which may store the encoded information. The Encoded Cells 622 may feature lower SER than the Memory Cells 616, e.g., more tolerant to SEU; note that for the same specific memory type, Encoded Cells 622 would be innately more robust against errors that Memory Cells 616 if the size (e.g., number of bits) of the Encoded Cells 622 is smaller than the Encoded Cells 622.

The signals include the Input Data 600, Output Data 602, Address 604 which are respectively signals functionally equivalent to the Input Data 200, Output Data 202, Address 204 in FIG. 2B. The First Memory Cell Array 614 and Second Memory Cell Array 624 may be within the same IC or separate ICs, integrated within the same package or in separate packages, etc. The functionality of the memory architecture in FIG. 6 is the same as that in FIG. 2B.

In the second embodiment of the disclosure, to achieve SER reduction for the memory architecture in FIG. 6 such that the Output Data 602 remains largely error-free, the Second Memory Cell Array 624 should have an SER lower than that of the First Memory Cell Array 614; this can be realized by one or a combination of methods (a)-(p), etc., delineated earlier. For example, the Second Memory Cell Array 624 may have 2× lower SER than that of the First Memory Cell Array 614. In this case, the encoded information in the Second Memory Cell Array 624 is unlikely to be corrupted by an error mechanism, e.g., SEU, so that the encoded information may effectively detect and correct an error for the data stored in the First Memory Cell Array 614.

The primary difference between the second embodiment of the disclosure in FIG. 6 and the prior-art system/method in FIG. 2 is that in the disclosure depicted in FIG. 6, the encoded cells (Encoded Cells 622) feature high robustness to errors (e.g., by one or a combination of methods (a)-(p), etc., delineated earlier) such as rad-hardened or embodying redundancy-more robust to errors than the memory cells (Memory Cells 616). Conversely, for the prior-art system/method in FIG. 2, the robustness against errors in memory cells (Memory Cells 616) and in encoded cells (Encoded Cells 622) would be the same, with no effort to make the robustness to errors different.

Note that in FIG. 6, the First Memory Cell Array 624 may be separate from or in the same physical entity with the Second Memory Cell Array 614. The EDAC Circuit 620 in FIG. 6 may perform the processing steps as illustrated FIG. 5A or FIG. 5B. The EDAC Circuit 620 may constitute as a part of the EDAC Processing 322 (as illustrated in FIG. 3).

In an implementation variation of the second embodiment of the disclosure, the robustness to errors of the EDAC Circuit 620 could be improved, e.g., realized by one or a combination of methods (a)-(p), etc. In a space application, rad-hardening may be appropriate to mitigate the possibility of SEU arising in the EDAC.

In another implementation of the second embodiment of the disclosure, the Input Data 600, the Output Data 602 and the Address 604 may collectively be forming a shared interface. In this case, the First Interface Protocol 306 and the Second Interface Protocol 316 in FIG. 3 may be the same.

Other possible implementation variations of the second embodiment may in part include using redundancy based on the Memory Cells 616 and the Encoded Cells 622. For example, the Memory Cells 616 and Encoded Cells 622 may be the same or different specific memory. Should the Memory Cells 616 and the Encoded Cells 622 be the same, the data protection may be by means dual-modular-redundancy. It is possible that the degree of redundancy applied to the Memory Cells 616 and Encoded Cells 622 be different, e.g., dual-redundancy and triple-redundancy, respectively.

Should the Memory Cells 616 and the Encoded Cells 622 be different, the data protection may be achieved via EDAC as described earlier where the Encoded Cells 622 may be in some fashion related to or resembling the Memory Cells 616 by means of encoding such as parity, Hamming, cyclic, hash function, etc. The Encoded cells 622 may comprise multiple copies of data where each copy of data may be in some fashion related to or resembling the Memory Cells 616. The multiple copies of data (of the Encoded Cells 622) may be protected by means of redundancy, from dual-modular-redundancy, TMR or higher modular redundancy (≥4). The adoption of redundancy may be in a spatial fashion (hardware-duplication), a temporal fashion (multiple executions at different times), a combination in the spatial and temporal fashions, etc.

The third embodiment of the disclosure is depicted in FIG. 7 as the pipeline structure vis-à-vis memory in the first two embodiments of the disclosure. The pipeline structure has a Datapath Combinational Logic 720, an EDAC Encoder 722, a First Flip-Flop 724, a Second Flip-Flop 726, and an EDAC Decoder 728. The signals include the Input 700, the Generated Data 702, the Encoded Info 704, the Possible Corrupted Generated Data 706, the Uncorrupted Encoded Info 708, and Corrected Data 710. The Input 700 may go through the Datapath Combinational Logic 720 to compute the Generated Data 702 which may be encoded by the EDAC Encoder 722 to compute the Encoded Info 704. The Generated Data 702 may be stored in the First Flip-Flop 724. If an error occurs in First Flip-Flop 724 (e.g., corrupted by an SEU), its output signal is erroneous as the Possible Corrupted Generated Data 706. The Encoded Info 704, on the other hand, may be stored in the Second Flip-Flop 726 which may be less likely be erroneous. This is because the robustness to error of the Second Flip-Flop is higher than that of the First Flip-Flop. The increased robustness to error of the Second Flip-Flip may be realized by one or a combination of methods (a)-(p), etc., delineated earlier. Hence the output signal of the Second Flip-Flop 726 is the Uncorrupted Encoded Info 708. The Possible Corrupted Generated Data 706 may be decoded by the EDAC Decoder 728 to produce the Corrected Data 710. The First Flip-Flop 724 and Second Flip-Flop 726 are usually integrated within the same IC die or package, albeit they can be in separate ICs or packages.

To achieve an SER reduction for the pipeline structure such that the Corrected Data 710 remains largely error-free, the Second Hardened Flip-Flop 726 should be more robust against error, i.e., have an SER lower, than that of the First Flip-Flop 724. For example, the Second Flip-Flop 726 may have 2× lower SER than that of the First Flip-Flop 724.

In an implementation variation of the third embodiment of the disclosure, the EDAC Encoder 722 and/or the EDAC Decoder 728 may feature high robustness to errors, e.g., radiation-hardened to mitigate the occurrence of SEU in a space application.

Other possible implementation variations of the third embodiment may in part using redundancy based on the First Flip-Flop 724 and the Second Flip-Flop 726. For example, the First Flip-Flop 724 and Second Flip-Flop 726 may be the same or different. Should the First Flip-Flop 724 and the Second Flip-Flop 726 be the same, enhanced data protection may be achieved by means dual-modular-redundancy. Should the First Flip-Flop 724 and the Second Flip-Flop 726 be different, the enhanced data protection may be achieved via EDAC as described earlier where Second Flip-Flop 726 may be in some fashion related to or resembling the First Flip-Flop 724 by means of encoding such as parity, Hamming, cyclic, etc. The Second Flip-Flop 726 may comprise multiple copies of data where each copy of data may be in some fashion related to or resembling the First Flip-Flop 724. The multiple copies of data (of the Second Flip-Flop 726) may be protected by means of redundancy, from dual-modular-redundancy, TMR or higher modular redundancy (≥4). The adoption of redundancy may be in a spatial fashion (hardware-duplication), a temporal fashion (multiple executions at different times), a combination in the spatial and temporal fashions, etc.

The means to enhance the robustness of Second Flip-Flop includes one or a combination of methods (a)-(p), etc., delineated earlier. This is also applicable to the EDAC Encoder 722, and the EDAC Decoder, etc.

The EDAC Encoder 722 and EDAC Decoder 728 may perform the processing steps as illustrated FIG. 5A or FIG. 5B. The EDAC Encoder 722 and EDAC Decoder 728 may form a part of the EDAC Processing 322 (as illustrated in FIG. 3).

The first embodiment of the disclosure as depicted in FIG. 3 may be further expanded as depicted in FIG. 8A where the First Memory IC 304 may comprise not only the Stored Data 308 but also Another Stored Encoded Information 802. The Another Stored Encoded Information 802 may be in some fashion related to or resembling the Stored Data 308 by means of encoding. The Another Stored Encoded Information 802 may be the same or different from the Stored Encoded Information 318 in the Second Memory IC 314. Should the Another Stored Encoded Information 802 and the Stored Encoded Information 318 be the same, the Another Stored Encoded Information 802 may provide redundancy to the Stored Encoded Information 318. The Another Stored Encoded Information 802 may comprise multiple copies of the data where each copy of data may be in some fashion related to or resembling the Stored Data 308. The multiple copies of data (of the Another Stored Encoded Information 802) may be protected by means of redundancy, from dual-modular-redundancy, TMR or higher modular redundancy (≥4). The adoption of redundancy may be in a spatial fashion (hardware-duplication), a temporal fashion (multiple executions at different times), a combination in the spatial and temporal fashions, etc.

Should the Another Stored Encoded Information 802 and the Stored Encoded Information 318 be different, the Another Stored Encoded Information 802 may provide a ‘no-error’ quick check for a decoding process. To enable a ‘no-error’ quick check, the Another Stored Encoded Information 802 may be in some fashion related to or resembling the Stored Data 308 by means of encoding such as parity, Hamming, cyclic, hash function, etc. The Another Stored Encoded Information 802 is encoded to map the Stored Data 308 to a code. During the decoding process, the Stored Data 308 may be re-mapped using the same encoding to generate another code. If the another code is the same as the Another Stored Encoded Information 802 (i.e., the code), the Stored Data 308 may be assumed to be error-free, hence no error correction is needed. If the another code is different from the Another Stored Encoded Information 802 (i.e., the code), the Stored Data 308 may likely have errors, hence needing the EDAC processing using the Stored Encoded Information 318 in the Second Memory IC 314. The conditional skip of the error correction may speed up the error detection or error correction or both error detection and correction because accessing the Stored Encoded Information 318 via the Second Interface Protocol 316 may be conditionally skipped, or the computational complexity in the EDAC Processing 322 may be conditionally reduced.

To enable a ‘no-error’ quick check with high accuracy, the Another Stored Encoded Information 802 may be encoded to be very sensitive to the Stored Data 308. The sensitivity may be defined where any datum corruption in either the Stored Data 308 or the Another Stored Encoded Information 802 may result in many errors when comparing the Another Stored Encoded Information 802 (i.e., the code) against the computed code using the Stored Data 308. A hash function may be used to improve the sensitivity for encoding the Another Stored Encoded Information 802. Possible hash functions may include cyclic redundancy check (CRC), Secure Hash Algorithm (SHA), Message Digest 5 (MD5), etc.

The first embodiment of the disclosure as depicted in FIG. 3 may be further expanded as depicted in FIG. 8B such that the Another Stored Encoded Information 804 may be stored in the Second Memory IC 318. The Another Stored Encoded Information 804 may be the same or different from the Stored Encoded Information 318 in the Second Memory IC 314. Should the Another Stored Encoded Information 804 and the Stored Encoded Information 318 be the same, the Another Stored Encoded Information 804 may provide redundancy to the Stored Encoded Information 318. The Another Stored Encoded Information 804 may comprise multiple copies of the data where each copy of data may be in some fashion related to or resembling the Stored Data 308. The multiple copies of data (of the Another Stored Encoded Information 804) may be protected by means of redundancy, from dual-modular-redundancy, TMR or higher modular redundancy (≥4). The adoption of redundancy may be in a spatial fashion (hardware-duplication), a temporal fashion (multiple executions at different times), a combination in the spatial and temporal fashions, etc.

Should the Another Stored Encoded Information 804 and the Stored Encoded Information 318 be different, the Another Stored Encoded Information 804 may provide a ‘no-error’ quick check for a decoding process. To enable a ‘no-error’ quick check, the Another Stored Encoded Information 804 may be in some fashion related to or resembling the Stored Data 308 by means of encoding such as parity, Hamming, cyclic, hash function, etc. The Another Stored Encoded Information 804 is encoded to map the Stored Data 308 to a code. During the decoding process, the Stored Data 308 may be re-mapped using the same encoding to generate another code. If the another code is the same as the Another Stored Encoded Information 804 (i.e., the code), the Stored Data 308 may be assumed to be error-free, hence no error correction is needed. If the another code is different from the Another Stored Encoded Information 804 (i.e., the code), the Stored Data 308 may likely have errors, hence needing the EDAC processing using the Stored Encoded Information 318 in the Second Memory IC 314. The conditional skip of the error correction may speed up the error detection or error correction or both error detection and correction because the computational complexity in the EDAC Processing 322 may be conditionally reduced.

For simplicity in the claim section, the Another Stored Encoded Information 802 or 804 may be viewed as the third data within either the First Memory IC 304 or the Second Memory IC 314, and the third data (i.e., the Another Stored Encoded Information 802 or 804) may comprise a datum (1 bit) or many data (multiple bits).

While several embodiments have been provided in the present disclosure, it should be understood that the disclosed systems and methods may be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted or not implemented. Of particular note, although the embodiments of the present disclosure are illustrated with an EDAC, the present disclosure is also applicable to electronic designs that do not embody an EDAC.

Also, techniques, systems, subsystems, and methods described and illustrated in the various embodiments as discrete or separate may be combined or integrated with other systems, modules, techniques, or methods without departing from the scope of the present disclosure. Other items shown or discussed as directly coupled or communicating with each other may be indirectly coupled or communicating through some interface, device, or intermediate component, whether electrically, mechanically, or otherwise. Other examples of changes, substitutions, and alterations are ascertainable by one skilled in the art and could be made without departing from the spirit and scope disclosed herein.

1. An electronic apparatus for detecting or correcting or detecting and correcting at least one datum error in an electronic device or electronic circuit or electronic system comprising:
a controller,
a first memory
connected with the controller, and
having a first data with an error or a number of errors,
and
a second memory
connected with the controller, and
having a second data with no error or with a number of errors that is lower than the number of errors in the first memory, and that is in some fashion related to or resembling the first data,
and
wherein the controller performs the error detection or the error correction or both the error detection and the error correction to the first data by using the second data.

2. The electronic apparatus in claim 1 wherein the second memory is more robust against errors than the first memory.

3. The electronic apparatus in claim 1 wherein the second memory is more robust from errors than the first memory or the second memory is different from the first memory by one or a combination of the following parameters:
physical address on the same integrated circuit die or location in different die, located in another integrated circuit die,
having one or more copies of the second data that is some fashion related to or resembling the first data in the first memory,
integrated circuit die,
data capacity of the first data and the second data,
fabrication process,
layout including the number or type of ring-guards,
interfacing circuit,
architecture or topology,
transistor configuration,
parasitic capacitance,
speed or delay,
power dissipation,
integrated circuit area,
operating voltage,
Radiation-Hardened-By-Design, or
Radiation-Hardened-By-Process.

4. The electronic apparatus in claim 1 wherein the controller computes redundancy using the first data or part of the first data and the second data or part of the second data, or
only the second data or part of the second data,
wherein the redundancy, in an either temporal or spatial fashion, includes one or a combination of the following:
dual-modular-redundancy,
triple-modular-redundancy, or
higher modular redundancies.

5. The electronic apparatus in claim 1 wherein the first memory or the second memory further have a third data that is in some fashion related to or resembling the first data, wherein the controller performs error detection or error correction or both error detection and error correction to the first data by using
the second data, or
the third data, or
both the second data and the third data.

6. The electronic apparatus in claim 1 further comprising a digital processor wherein
the digital processor is a
computational device,
microprocessor,
microcontroller,
state-machine, or
a field programmable gate array,
and
the controller is either
embedded in the digital processor,
its functionality realized by the digital processor, or
a separate electronic device or electronic circuit connected to the digital processor.

7. An electronic apparatus for detecting or correcting or both detecting and correcting at least one datum with error in an electronic device or electronic circuit or electronic system comprising:
a first memory having a first data with an error or a number of errors,
and
a second memory having a second data whose information is either identical to, or in some fashion related to or resembling the first data,
wherein the error detection or the error correction or both the error detection and the error correction to the first data is based on using the second data.

8. The electronic apparatus in claim 7 wherein the second memory is more robust against errors than the first memory.

9. The electronic apparatus according to claim 7, wherein the second memory comprises:
a first encoded data or at least a copy of the first encoded data, wherein
the first encoded data is in some fashion related to or resembling the first data, or
a second encoded data or at least a copy of the second encoded data, wherein
the second encoded data is in some fashion related to or resembling the first data, or
combination of the first encoded data, the at least a copy of the first encoded data, the second encoded data or the at least a copy of the second encoded data,
wherein
the first encoded data and the second encoded data are the same or different,
the error detection or the error correction or both the error detection and the error correction to the first data uses one or more of the following:
the first encoded data or the at least a copy of the first encoded data,
the second encoded data or the at least a copy of the second encoded data, or
a combination of the first encoded data, the at least a copy of the first encoded data, the second encoded data, or the at least a copy of the second encoded data.

10. The electronic apparatus according to claim 7, wherein
the first memory or the second memory further comprises a third data that is in some fashion related to or resembling the first data,
and
wherein the error detection or the error correction or both the error detection and the error correction to the first data uses
the second data, or
the third data of the first memory or the third data of the second memory, or
both the second data and
the third data of the first memory, or
the third data of the second memory.

11. The electronic apparatus according to claim 10, wherein
the error detection to the first data uses the third data of the first memory or of the second memory, wherein either
when an error is detected,
the error correction to the first data uses the second data,
or
otherwise when no error is detected,
no error correction is performed to the first data.

12. The electronic apparatus according to claim 9, wherein
the first memory further comprises a third encoded data which is in some fashion related to or resembling the first data,
the second data comprises one or both of the following:
the first encoded data comprising a copy of the third encoded data, or
the at least a copy of the first encoded data,
and
the error detection or the error correction or both the error detection and the error correction to the first data by
using the third encoded data, and
either the first encoded data, the at least a copy of the first encoded data or combination of the first encoded data or the at least a copy of the first encoded data.

13. The electronic apparatus according to claim 9 wherein the first encoded data or the second encoded data or both the first and second encoded data is encoded by one or more of the following combinations:
parity,
Hamming,
cyclic, or
hash function.

14. The electronic apparatus according to claim 7 wherein the error in the datum of the first memory is due to a fault by either one or more of the following combinations:
during the writing into the address of the memory location that would store the datum or data,
an erroneous change of the datum or data during storage, or
during the reading of the address of the memory location that embodies the datum or data.

15. The electronic apparatus in claim 7 wherein for the first data and the second data,
the data capacity or the number of bits of the second data is either the same or different from the data capacity or the number of bits of the first data,
and
they have different addresses in the same memory integrated circuit die, or are in physically different memory integrated circuit dies.

16. The electronic apparatus in claim 7 wherein
the first data comprises at least a memory bit,
and
the second data comprises either one or both
the at least memory bit, or
at least an encoded bit that is in some fashion related to or resembling the first data.

17. The electronic apparatus in claim 10 wherein
the third data of the first memory or of the second memory or of both the first and second memories comprises at least a bit encoded by one or more of the following combinations:
parity,
Hamming,
cyclic, or
hash function.

18. The electronic apparatus in claim 7 wherein the second memory is more robust from errors than the first memory or the second memory is different from the first memory by one or a combination of the following parameters:
physical address on the same integrated circuit die or location in different die having one or more copies of the second data that is some fashion related to or resembling the first data in the first memory,
integrated circuit die,
data capacity of the first data and the second data,
fabrication process,
layout including the number or type of ring-guards,
interfacing circuit,
architecture or topology,
transistor configuration,
parasitic capacitance,
speed or delay,
power dissipation,
integrated circuit area,
operating voltage,
Radiation-Hardened-By-Design, or
Radiation-Hardened-By-Process.

19. The electronic apparatus according to claim 7 wherein the error detection or the error correction or both the error detection and the error correction involves an encoding operation, a decoding operation or both an encoding and a decoding operation,
wherein during the encoding operation,
the first data to be written is encoded as an encoded data that provides data integrity information,
the first data is written into the first memory,
the encoded data is written as the second data into the second memory,
and
wherein during the decoding operation,
the first data in the first memory is read,
the second data in the second memory is read and decoded, and
if there is a discrepancy between the read first data and the read-and-decoded second data,
the read first data is corrected by using the read-and-decoded second data.

20. The electronic apparatus according to claim 10 wherein the error detection or the error correction or both the error detection and the error correction involves an encoding operation, a decoding operation or both an encoding and a decoding operation, wherein
during the encoding operation,
the first data to be written is encoded as two encoded data that provide data integrity information,
the first data is written into the first memory,
one of the two encoded data is written as the second data into the second memory, the other one of the two encoded data is written as the third data in the first memory or in the second memory,
and
during the decoding operation,
the first data in the first memory is read,
the second data in the second memory is read and decoded,
the third data in the first memory or in the second memory is read and decoded, and
if there is a discrepancy between the read first data and either the read-and-decoded second data or the read-and-decoded third data,
the read first data is corrected by using
the read-and-decoded second data from the second memory,
the read-and-decoded third data, or
both the read-and-decoded second and the third data.

21. A method to detect or correct or both detect and correct at least one datum with error in an electronic device or electronic circuit or electronic system comprising:
at least one of detecting an error to a first data in a first memory or correcting the error to the first data in the first memory using a second data stored in a second memory, wherein the second data of the second memory is either identical to, or in some fashion related to or resembling the first data of the first memory.

22. The method in claim 21 wherein the second memory is more robust against errors than the first memory.

23. The method in claim 21 wherein the first memory or the second memory further comprises a third data that is in some fashion related to or resembling the first data, wherein the at least one of detecting the error to the first data in the first memory or correcting the error to the first data in the first memory is by using the second data, or the third data, or both the second data and the third data.
